(19) United States
(12) Patent Application Publication
(10) Pub. No.: US 2025/0221318 A1
(43) Pub. Date: Jul. 3, 2025

(54) MAGNETOELECTRIC SPIN–ORBIT (MESO) DEVICE WITH ANTIFERROMAGNETIC SPIN INJECTION AND SPIN ABSORPTION FOR INCREASED OUTPUT VOLTAGE

(71) Applicant: Intel Corporation, Santa Clara, CA (US)

(72) Inventors: Mahendra DC, Portland, OR (US); Punyashloka Debashis, Hillsboro, OR (US); Dmitri Evgenievich Nikonov, Beaverton, OR (US); Hai Li, Portland, OR (US); Ian Alexander Young, Olympia, WA (US); Marko Radosavljevic, Portland, OR (US); John J. Plombon, Portland, OR (US); Scott B. Clendenning, Portland, OR (US); Carly Rogan, North Plains, OR (US); Dominique A. Adams, Portland, OR (US)

(73) Assignee: Intel Corporation, Santa Clara, CA (US)

(21) Appl. No.: 18/401,424

(22) Filed: Dec. 30, 2023

(51) Int. Cl. H10N 50/20; H10N 50/85

(52) U.S. Cl. CPC H10N 50/20; H10N 50/85

(57) ABSTRACT

Magnetoelectric spin-orbit (MESO) devices, integrated circuit devices and systems with MESO devices, and methods of forming the same, are disclosed herein. In one embodiment, a semiconductor device includes: a first layer that includes a magnetoelectric material; one or more second layers over the first layer, where the second layer(s) include one or more ferromagnetic materials; a third layer over the second layer(s), where the third layer includes an antiferromagnetic material; and a fourth layer over the third layer, where the fourth layer includes at least one of a metal, a topological insulator, or a two-dimensional (2D) semiconductor material.

### BACKGROUND

Magnetoelectric spin-orbit (MESO) logic is a type of spintronic logic that operates using the magnetoelectric effect in conjunction with the spin-orbit coupling effect (e.g., the coupling of an electron's inherent angular momentum with its translational orbital motion). For example, magnetoelectric switching can be used to convert an input voltage/charge into a magnetic spin state (e.g., charge-to-spin conversion), and spin-orbit transduction can be used to convert the magnetic spin state back into an output charge/voltage (e.g., spin-to-charge conversion). During the spin-to-charge conversion, however, spin injection inefficiencies and spin backflow can lead to lower output voltage, which makes it challenging to cascade MESO devices together to form large-scale integrated circuits.

### BRIEF DESCRIPTION OF THE DRAWINGS

FIG. 1 illustrates an example of a MESO device with antiferromagnetic spin injection and spin absorption layers.

FIGS. 2A-D illustrate an example process flow for forming a MESO device with antiferromagnetic spin injection and spin absorption layers.

FIG. 3 illustrates an example of cascaded MESO logic.

FIG. 4 illustrates a flowchart for forming integrated circuitry with one or more MESO devices in accordance with certain embodiments.

FIG. 5 is a top view of a wafer and dies that may be included in a microelectronic assembly.

FIG. 6 is a cross-sectional side view of an integrated circuit device that may be included in a microelectronic assembly.

FIG. 7 is a cross-sectional side view of an integrated circuit device assembly that may include a microelectronic assembly.

FIG. 8 is a block diagram of an example electrical device that may include a microelectronic assembly.

### DETAILED DESCRIPTION

Spintronic logic refers to a class of semiconductor devices that leverage the physical properties of magnetization—such as the spin of electrons and their magnetic moments—to represent and manipulate data. As an example, the magnetic spin state of electrons can be used to represent logic states, logic values, bits, compute variables, and so forth.

Magnetoelectric spin-orbit (MESO) logic is a type of spintronic logic that operates using the magnetoelectric effect in conjunction with the spin-orbit coupling effect (e.g., the coupling of an electron's inherent angular momentum with its translational orbital motion). In particular, the magnetoelectric effect is used to control or manipulate the spin state of a magnet, and the spin-orbit coupling effect is used to read out the spin state of the magnet. For example, magnetoelectric switching can be used to convert charge produced by an input voltage into a magnetic spin state (e.g., charge-to-spin conversion), and spin-orbit transduction can be used to convert the magnetic spin state back into charge (e.g., spin-to-charge conversion) to produce an output voltage.

In some embodiments, for example, MESO logic can be used to implement a non-volatile logic device, such as a logic switch/gate with a non-volatile logical state. For example, a MESO logic device can convert a logical state represented by an input voltage/charge into a (non-volatile) magnetic spin state, and then subsequently convert the magnetic spin state back into an output charge/voltage to read out the logical state. Moreover, since the magnetic spin state is non-volatile, the logical state is preserved when power is switched off, which means a MESO logic device is extremely energy efficient.

As a result, MESO logic devices are a super-energy-efficient alternative to complementary metal-oxide-semiconductor (CMOS) logic devices (e.g., CMOS transistors). For example, analogous to CMOS devices, MESO logic devices can be used to implement logic circuitry in scalable integrated circuits. Compared to CMOS technology, however, MESO logic has superior energy efficiency (e.g., lower energy consumption for switching, which translates into lower operating voltage), higher integration density and efficiency (e.g., more logic functions per unit area, fewer devices required per logic function), and non-volatility (e.g., which counteracts leakage power and enables ultralow standby power).

One of the challenges associated with designing MESO logic, however, is ensuring that the output signal of one MESO device is large enough to drive the input of other MESO devices. For example, MESO logic is typically implemented as a collection of cascaded MESO devices, where the output of one MESO device serves as the input to one or more other MESO devices. As a result, the output signal of each MESO device needs to be high enough to drive the input signal to the next MESO device(s).

The output power of a MESO device is dependent on the efficiency of the spin-to-charge conversion readout, however, which can be a limiting factor in achieving high output voltage.

For example, to read out the direction of magnetization induced on the magnet, a voltage (V_{DD}) is applied to cause charge current (I_{SUPPLY}) to flow into the magnet, which in turn causes the magnet to produce spin polarized current whose spin polarization aligns with the direction of magnetization in the magnet. The spin polarized current in the magnet is injected into a spin-orbit coupling (SOC) readout layer with high spin-orbit coupling, where the spin polarized current is converted into charge current due to the inverse spin Hall effect (ISHE) or inverse Rashba-Edelstein effect (IREE). As a result, an output voltage (+−V_{OUT}) is produced with a polarity corresponding to the direction of magnetization in the magnet, which serves as the output of the MESO device.

During the spin-to-charge conversion, however, spin injection inefficiencies and spin backflow may result in a lower output voltage. For example, with respect to spin current injected from the magnet to the SOC layer, some of the spin current may not reach the SOC layer, as spins may dissipate at the interface of the magnet and the SOC layer (e.g., due to scattering, conductance mismatch, lattice mismatch), which reduces the output voltage. A thin insulating oxide layer can be inserted between the magnet and the SOC layer to improve spin injection efficiency, but not all of the spin current will reach the SOC layer. Further, the SOC layer is typically capped with an oxide insulating layer for protection, but the insulating layer can cause spin backflow that reduces the output voltage. For example, spin current that is not absorbed by the SOC layer can be reflected back at the interface of the SOC layer and the insulating layer, which results in spin backflow that cancels or kills the injected spin current in the SOC layer, thus reducing the output voltage.

Accordingly, this disclosure presents embodiments of MESO devices with antiferromagnetic spin injection and/or spin absorption layers to increase output voltage. In some embodiments, an insulating antiferromagnetic (AFM) layer (e.g., nickel oxide (NiO), cobalt oxide (CoO)) may be inserted at the interface between the ferromagnet (FM) layer and the spin-orbit coupling (SOC) layer to increase spin injection efficiency. The insulating AFM layer injects spin current from the FM layer into the SOC layer more efficiently using magnons, which enhances the read output voltage. Further, in some embodiments, the SOC layer may be capped with a spin absorption layer (e.g., ruthenium (Ru)) instead of an oxide insulation layer. In this manner, any spin current that is not absorbed by the SOC layer will be absorbed by the spin absorption layer instead of being reflected back into the SOC layer, thus eliminating or reducing spin backflow that kills injected spin current in the SOC layer.

The described embodiments may provide various advantages, including enhanced spin injection efficiency and higher read output voltage. In some cases, for example, the enhanced spin injection efficiency may increase the output voltage by a factor of 10. In particular, the AFM layer increases spin injection efficiency and causes more spin current to reach the SOC layer, which results in higher output voltage. In addition, the AFM layer is polycrystalline and antiferromagnetic ordering is not necessary. Further, the spin absorption layer decreases or eliminates spin backflow in the SOC layer, thus preventing injected spin current from being cancelled, which also results in higher output voltage.

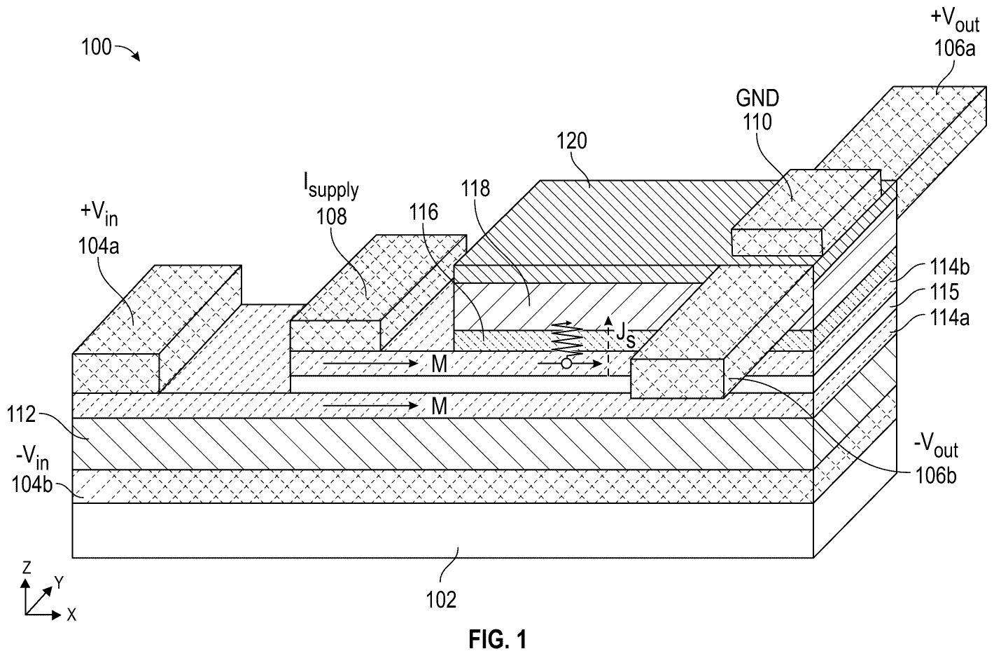

FIG. 1 illustrates an example of a magnetoelectric spin-orbit (MESO) device 100 with antiferromagnetic spin injection and spin absorption layers for spin-to-charge conversion. For example, an insulating antiferromagnetic (AFM) spin injection layer 116 (e.g., nickel oxide (NiO), cobalt oxide (CoO)) is inserted at the interface between the ferromagnet (FM) layers 114a,b (collectively, FM 114) and the spin-orbit coupling (SOC) layer 118 to inject spin current from the FM 114 into the SOC layer 118 more efficiently using magnons, which increases spin injection efficiency and enhances the read output voltage. Further, the SOC layer 118 is capped with a spin absorption layer 120 (e.g., ruthenium (Ru)) to absorb spin current that is not absorbed by the SOC layer 118, thus eliminating or reducing spin backflow that may cancel injected spin current in the SOC layer 118, which further enhances the read output voltage.

In the illustrated embodiment, for example, charge current injected into the FM 114 is converted into spin current, which transfers spin angular momentum to the insulating AFM layer 116. Due to the exchange interaction between spin current from the FM 114 and antiferromagnetic moments of the insulating AFM layer 116, magnonic current is generated in the insulating AFM layer 116 (e.g., as shown by the spin waves in AFM layer 116). The magnonic current, also known as magnons, transfers spin into free electrons in the SOC layer 118. The free electrons become spin polarized and scattered in the SOC layer 118, and the spin-polarized current is converted into charge current due to the inverse spin Hall effect and/or inverse Edelstein/Rashba-Edelstein effect. For example, the SOC layer 118 is made of material with high spin-orbit coupling, such as heavy metals, topological insulators, and/or two-dimensional (2D) semiconductor materials. In heavy metals, the free electrons become spin polarized and scattered and are converted into charge current due to the inverse spin Hall effect. In topological insulators and 2D materials, the spin-polarized current is converted into charge current due to the inverse Edelstein/Rashba-Edelstein effect.

The magnonic spin injection (e.g., spin injection via magnons) of the AFM layer 116 is extremely efficient and increases the output voltage significantly (e.g., up to 10×). Growth of the insulating AFM layer 116 is also compatible with large-scale production, as the AFM layer 116 can be grown using physical vapor deposition (PVD) and no epitaxy is required for the growth. In addition, antiferromagnetic order is unnecessary.

Further, in the illustrated embodiment, the SOC layer 118 is capped with a spin absorption layer 120 to absorb spin current that is not absorbed by the SOC layer 118. For example, some of the spin current injected into the SOC layer 118 may not be absorbed by the SOC layer 118 and may instead reach the following layer, which is typically a protective capping layer over the SOC layer 118. In some MESO designs, the protective capping layer is made of an oxide insulator (e.g., magnesium oxide (MgO), aluminum oxide (AlO)), which can cause spin backflow that reduces the output voltage. For example, spin current that reaches the oxide insulator may be reflected back into the SOC layer by the oxide insulator, which results in spin backflow that cancels or kills the injected spin current in the SOC layer, thus reducing the output voltage. In the illustrated embodiment, however, the SOC layer 118 is capped with a spin absorption layer 120, which is made of a material with high spin absorption, such as ruthenium (Ru). As a result, any spin current that is not absorbed by the SOC layer 118 will be absorbed by the spin absorption layer 120 instead of being reflected back into the SOC layer 118, thus eliminating or reducing spin backflow that kills injected spin current in the SOC layer 118, which increases the output voltage.

The full operation of MESO device 100 will now be described in further detail. In the illustrated embodiment, MESO device 100 includes a substrate 102, a magnetoelectric (ME) layer 112, ferromagnetic (FM) layers 114a-b separated by an FM insulator layer 115 (collectively referred to as ferromagnet (FM) 114), an antiferromagnetic (AFM) injection layer 116, a spin-orbit coupling (SOC) layer 118, and a spin absorption layer 120. MESO device 100 also includes electrical contacts (e.g., conductive contacts, lines, traces, interconnects, electrodes) for differential input voltages (+−V_{IN}) 104a-b, differential output voltages (+−V_{OUT}) 106a-b, a power supply (I_{SUPPLY}) 108, and ground (GND) 110.

The FM layers 114a-b and the intervening FM insulation layer 115 collectively function as a single ferromagnet (e.g., when the direction of magnetization changes on one of the ferromagnets 114a-b, it also changes on the other) and may collectively be referred to as ferromagnet (FM) 114 or magnet 114. Moreover, the FM layers 114a-b are made of a ferromagnetic material that retains the magnetization setting induced on them, which means the ferromagnet 114 is non-volatile.

The differential input voltage (+−V_{IN}) controls the direction of magnetization induced on the magnet 114, while a supply voltage (V_{DD}) causes the direction of magnetization to be read out from the magnet 114 as a transverse differential output voltage (+−V_{OUT}). For example, when a differential input voltage (+−V_{IN}) is applied on the +−V_{IN} contacts 104a-b, the magnetoelectric (ME) layer 112 performs charge-to-spin conversion to convert electric charge current from the input voltage (+−V_{IN}) into a magnetic spin state (e.g., a particular direction of magnetization) in the magnet 114. When a supply voltage (V_{DD}) is applied on the I_{SUPPLY} contact 108, the SOC layer 118 performs spin-to-charge conversion to convert the magnetic spin state (e.g., the direction of magnetization) in the magnet 114 back into an electric charge current, which produces a transverse output voltage (+−V_{OUT}) on the +−V_{OUT} contacts 106a-b.

For example, in order to change the direction of magnetization on the magnet 114, a differential input voltage (+−V_{IN}) is applied on the +−V_{IN} contacts 104a-b, which causes charge current (I_{IN}) to flow through the +−V_{IN} contacts 104a-b and into the ME layer 112. The charge current (IN) ferroelectrically polarizes the ME layer 112, which causes the ME layer 112 to induce a particular direction of magnetization in the magnet 114.

In particular, the ME layer 112 is made from a magnetoelectric material that has both magnetic and electrical properties. Moreover, the ME layer 112 is configured as a magnetoelectric (ME) capacitor, with the +−V_{IN} contacts 104a-b and the magnet 114 serving as the electrical plates surrounding the ME capacitor layer 112. When charge current (I_{IN}) flows into the ME layer 112, the ferroelectric polarization of the ME layer 112 causes an electric field to form in the +−Z direction depending on the polarity of the current (I_{IN}).

For example, when a positive differential input voltage (+−V_{IN}) is applied, the current flow is positive (e.g., in the +X direction) and an electric field forms in the −Z direction in the ME layer 112. By contrast, when a negative differential input voltage (+−V_{IN}) is applied, the current flow is negative (e.g., in the −X direction) and an electric field forms in the +Z direction in the ME layer 112.

As charge accumulates in the ME layer 112, the spin of electrons in the ME layer 112 become aligned at the interface with the ferromagnet 114 to form surface spin polarization, thus forming a magnetic field. The direction of magnetization (e.g., spin) of the magnetic field is defined by the direction of ferroelectric polarization in the ME layer 112. Further, as the magnetic field corresponding to the surface spin polarization is formed, it becomes exchange coupled with the ferromagnet 114, causing the magnetization in the ferromagnet 114 to align with the magnetic field of the surface spin polarization in the ME layer 112.

The direction of magnetization in the ferromagnet 114 is in plane (e.g., parallel to plane) in either the +−X direction (e.g., as shown by the arrows on the ferromagnet 114), depending on the polarity of the input voltage (+−V_{IN}) and the corresponding ferroelectric polarization in the ME layer 112. In this manner, the direction of magnetization in the ferromagnet 114 can be controlled or switched by reversing the polarity of the input voltage (+−V_{IN}) (e.g., applying either positive or negative input voltage). Further, due to its ferromagnetic properties, the magnet 114 retains the induced direction of magnetization even after the input voltage (+−V_{IN}) is switched off (e.g., the magnet 114 is non-volatile).

In order to read out the direction of magnetization from the magnet 114, a supply voltage (V_{DD}) is applied on the power supply contact 108, which causes charge current (I_{SUPPLY}) to flow through the power supply contact 108 and into the magnet 114, which in turn causes the magnet 114 to produce spin polarized current whose spin polarization aligns with the direction of magnetization in the magnet 114. The spin polarized current in the magnet 114 is then injected into the SOC layer 118 via the antiferromagnetic spin injection layer 116 (e.g., using magnonic current or magnons, as described further above). The SOC layer 118 converts the spin polarized current into charge current due to the inverse spin Hall effect (ISHE) and/or inverse Rashba-Edelstein effect (IREE). Further, the spin absorption layer 120 absorbs any spin current that is not absorbed by the SOC layer 118, thus avoiding any spin backflow that could potentially cancel the injected spin current in the SOC layer 118 (e.g., as described further above). The resulting charge current in the SOC layer 118 flows in a perpendicular direction, which produces a transverse differential output voltage (+−V_{OUT}) on the +−V_{OUT} contacts 106a-b. The polarity of the output voltage (+−V_{OUT}) indicates the direction of magnetization of the magnet 114, which serves as the output of the MESO device 100.

The substrate 102 may be made of any suitable substrate material(s), including, without limitation, dysprosium scandium oxide (DSO) (e.g., DyScO₃) or silicon (Si). For example, in some embodiments, the substrate 102 may be a DSO substrate, or a silicon substrate with an inserted templating layer. Thus, in some embodiments, the substrate 102 may be made of material(s) that include elements such as dysprosium (Dy), scandium (Sc), oxygen (O), and/or silicon (Si).

The conductive contacts/interconnects for +−V_{IN}, +−V_{OUT}, I_{SUPPLY}, and GND (104a-b, 106a-b, 108, 110) may be made of any suitable conductive material(s), including, without limitation, material(s) that include elements such as titanium (Ti), gold (Au), copper (Cu), silver (Ag), aluminum (Al), cobalt (Co), tungsten (W), tantalum (Ta), nickel (Ni), and/or graphene. For example, in some embodiments, the conductive contacts may be made of one or more materials that include titanium (Ti) and gold (Au).

The ME layer 112 may be made of any suitable magnetoelectric and/or multiferroic material(s), including, but not limited to: (i) multiferroics such as bismuth ferrite (BFO) (e.g., BiFeO₃), lanthanum doped bismuth ferrite (LBFO) (e.g., LaBiFeO₃), samarium doped bismuth ferrite (e.g., SmBiFcO₃), lutetium ferrite (LFO) (e.g., LuFeO₂, LuFeO₃, LuFe₂O₄), TbMnO₃, and other multiferroic oxides; (ii) magnetostrictive materials such as Fe₃Ga, TbₓDy₁₋ₓFe₂, FeRh; (iii) electrically tuned exchange-mediated magnetoelectrics such as Cr₂O₃ and Fe₂TeO₆; and/or (iv) any other suitable materials with magnetoelectric properties, such as BiTiO₃, lead zirconate titanate (PZT), lead magnesium niobate-lead titanate (PMN-PT), and aluminum nitride (AlN). Thus, in some embodiments, the ME layer 112 may be made of material(s) that include elements such as bismuth (Bi), iron (Fe), oxygen (O), lanthanum (La), samarium (Sm), lutetium (Lu), terbium (Tb), manganese (Mn), gallium (Ga), dysprosium (Dy), rhodium (Rh), chromium (Cr), tellurium (Te), aluminum (Al), nitrogen (N), titanium (Ti), magnesium (Mg), zirconium (Zr), niobium (Nb), and/or lead (Pb).

The FM layers 114a-b may be made of any suitable magnetic or ferromagnetic material(s), including, without limitation, cobalt iron (CoFc), nickel iron (NiFe), LaSrMnO₃, and/or Co-doped or Fe-doped perovskite oxide (e.g., CaTiO₃). Thus, in some embodiments, the FM layers 114a-b may be made of material(s) that include elements such as cobalt (Co), iron (Fe), nickel (Ni), gadolinium (Gd), lanthanum (La), strontium (Sr), manganese (Mn), oxygen (O), calcium (Ca), and/or titanium (Ti).

The FM insulation layer 115 may be made of any suitable insulating or dielectric material(s), including, without limitation, magnesium oxide (MgO), aluminum oxide (AlO) (e.g., Al₂O₃), titanium oxide (TiO) (e.g., TiO₃), silicon oxide (SiO) (e.g., SiO₂), silicon nitride (SiN) (e.g., Si₃N₄), and/or hafnium oxide (HfO) (e.g., HfO₂). Thus, in some embodiments, the FM insulation layer 115 may be made of material(s) that include elements such as magnesium (Mg), aluminum (Al), titanium (Ti), hafnium (Hf), silicon (Si), oxygen (O), and/or nitrogen (N).

The AFM injection layer 116 may be made of any suitable antiferromagnetic material(s) and/or antiferromagnetic insulator(s), including, without limitation, nickel oxide (NiO) and/or cobalt oxide (CoO). For example, in some embodiments, the AFM injection layer 116 may be a single layer of polycrystalline nickel oxide (NiO) or polycrystalline cobalt oxide (CoO) with a thickness of approximately 1-2 nanometers (nm). Thus, in some embodiments, the AFM injection layer 116 may be made of material(s) that include elements such as nickel (Ni), cobalt (Co), and/or oxygen (O).

The SOC layer 118 may be made of any suitable SOC material(s) with relatively high spin-orbit coupling, which includes elements with a relatively high SOC coefficient and/or relatively high atomic number (as spin-orbit coupling is directly proportional to atomic number), such as heavy metals, topological insulators, and/or two-dimensional (2D) semiconductor materials. Examples of heavy metals that may be used in the SOC layer 118 include, without limitation, platinum (Pt), tantalum (Ta), and/or tungsten (W). Examples of topological insulators that may be used in the SOC layer 118 include, without limitation, bismuth selenide (BiSe), bismuth antimony telluride (BiSbTe), antimony telluride (SbTe), and/or bismuth antimonide (BiSb). Examples of 2D semiconductor materials that may be used in the SOC layer 118 include, without limitation, transition-metal dichalcogenides (TMD) (e.g., TMD monolayers) and/or graphene (e.g., graphene monolayers). A TMD may refer to an atomically thin semiconductor of the type MX₂, where M is a transition-metal atom (e.g., tungsten (W)) and X is a chalcogen atom (e.g., selenium (Se), sulfur(S)), and one layer of M atoms is sandwiched between two layers of X atoms. Graphene may refer to an allotrope of carbon (C) with a single layer of atoms. Thus, in some embodiments, the SOC layer 118 may be made of material(s) that include elements such as platinum (Pt), tantalum (Ta), tungsten (W), bismuth (Bi), selenium (Se), antimony (Sb), tellurium (Te), sulfur(S), and/or carbon (C).

The spin absorption layer 120 may be made of any suitable material(s) with relatively high spin absorption properties, including, without limitation, ruthenium (Ru). In some embodiments, for example, the spin absorption layer 120 may be a single layer of ruthenium (Ru) with a thickness of approximately 1-2 nanometers (nm). Alternatively, the spin absorption layer 120 may be made of any suitable material(s) with a relatively short spin diffusion length, such as tantalum (Ta). If a material with short spin diffusion length has a negative spin Hall angle, (e.g., tantalum (Ta)), the spin absorption layer 120 may have a thickness of approximately 1 nm. If a material with short spin diffusion length has a positive spin Hall angle, however, the spin absorption layer 120 may have a thickness of approximately 0.5 nm. In some embodiments, for example, the spin absorption layer 120 may be a single layer of tantalum (Ta) with a thickness of approximately 1 nm. Thus, in some embodiments, the spin absorption layer 120 may be made of material(s) that include elements such as ruthenium (Ru) and/or tantalum (Ta).

Further, in various embodiments, MESO device 100 may be implemented using other types, numbers, and/or arrangements of layers and materials than those shown and described with respect to FIG. 1. For example, certain components of MESO device 100 may be added, replaced, omitted, and/or rearranged. Some embodiments may include both the AFM layer 116 and the spin absorption layer 120, while others may include only the AFM layer 116 or only the spin absorption layer 120. A layer may refer to one or more layers of material, such as a single layer of material, or a stack of layers.

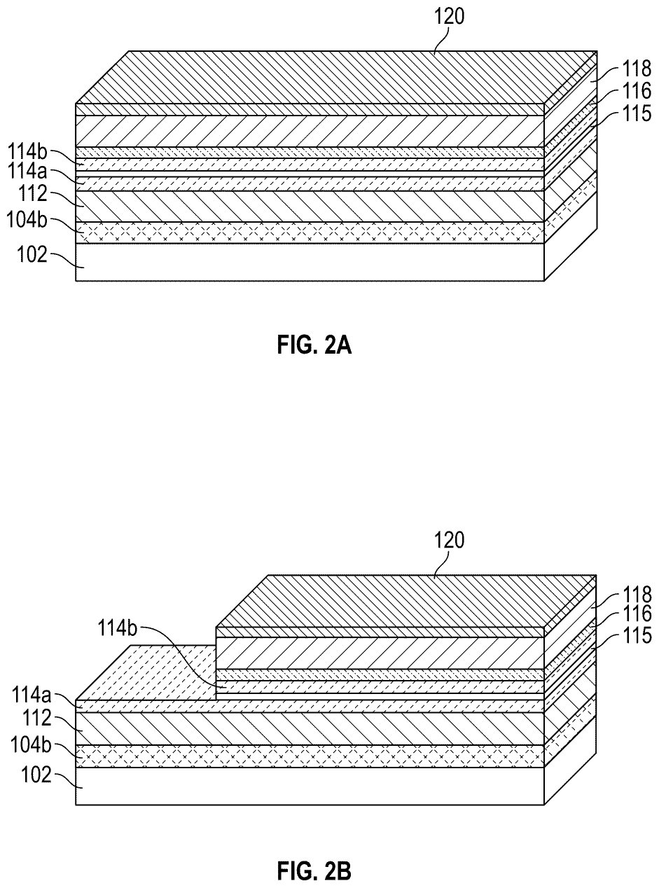

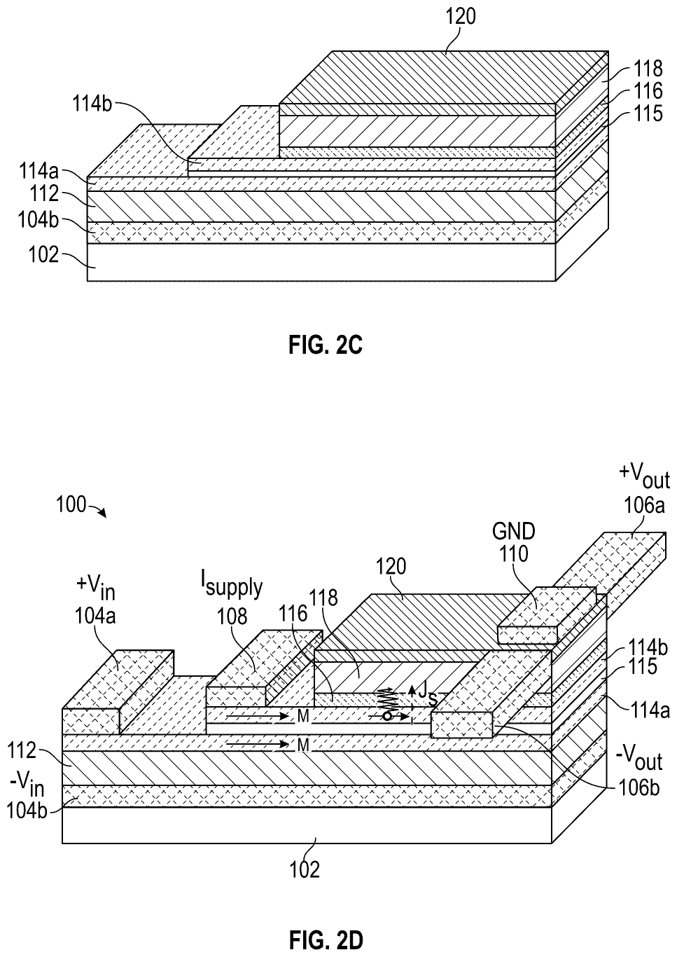

FIGS. 2A-D illustrate an example process flow for forming a MESO device 100 with antiferromagnetic spin injection and spin absorption layers. The illustrated process flow is used to form the MESO device 100 of FIG. 1. It will be appreciated in light of the present disclosure that the illustrated process flow is only one example methodology for arriving at MESO device 100.

In FIG. 2A, a stack of layers is formed over a substrate 102, including a conductive layer 104b for one of the differential voltage inputs (e.g., −V_{IN}), a magnetoelectric (ME) layer 112, a first ferromagnetic (FM) layer 114a, an FM insulator layer 115, a second FM layer 114b, an antiferromagnetic layer 116, a spin-orbit coupling (SOC) layer 118, and a spin absorbing layer 120.

The −V_{IN} layer 104b is over the substrate 102, the ME layer 112 is over the −V_{IN} layer 104b, the first FM layer 114a is over the ME layer 112, the FM insulator layer 115 is over the first FM layer 114a, the second FM layer 114b is over the FM insulator layer 115, the AFM layer 116 is over the second FM layer 114b, the SOC layer 118 is over the AFM layer 116, and the spin absorbing layer 120 is over the SOC layer 118.

In FIG. 2B, portions of the FM insulator layer 115, second FM layer 114b, AFM layer 116, SOC layer 118, and spin absorbing layer 120 are etched (e.g., using ion milling) to open up an area above the first FM layer 114a.

In FIG. 2C, portions of AFM layer 116, SOC layer 118, and spin absorbing layer 120 are etched (e.g., using ion milling) to open up an area above the second FM layer 114b.

In FIG. 2D, the remaining conductive layers/contacts are formed for the other differential voltage input (+V_{IN}) 104a, the different voltage outputs (+−V_{OUT}) 106a-b, power supply (I_{SUPPLY}) 108, and ground (GND) 110. For example, the second differential voltage input (+V_{IN}) contact 104a is formed over the first FM layer 114a, the different voltage output (+−V_{OUT}) contacts 106a-b are formed on each side of the SOC layer 118 and spin absorption layer 120 (extending perpendicular from therefrom), the power supply (I_{SUPPLY}) contact 108 is formed over the second FM layer 114b, and the ground (GND) contact 110 is formed over the spin absorption layer 120.

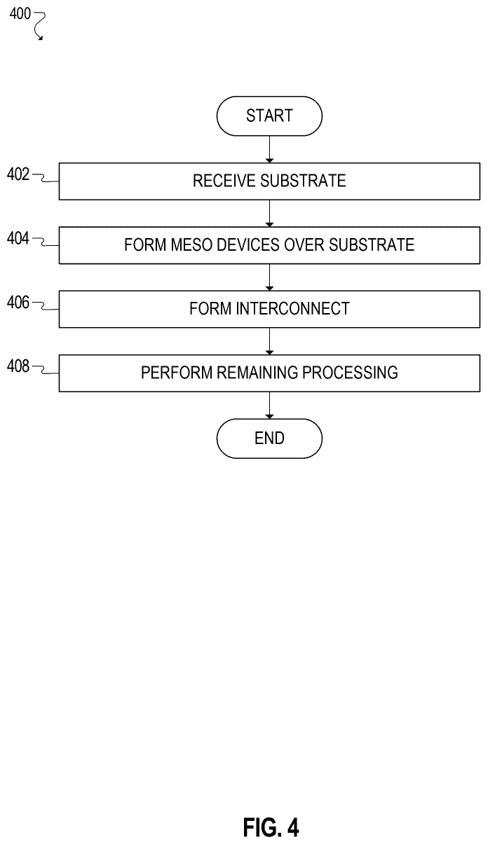

At this point, the MESO device 100 may be complete. In some embodiments, however, additional processing may be performed, as described below with respect to the process flow of FIG. 4.

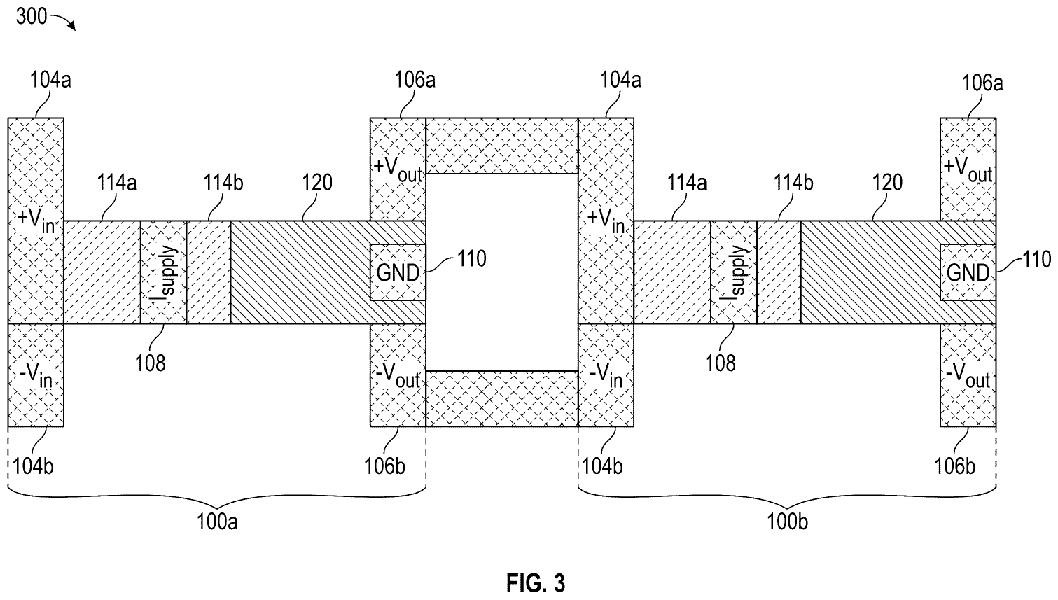

FIG. 3 illustrates an example of cascaded MESO logic 300. In the illustrated embodiment, the cascaded MESO logic 300 includes multiple cascaded MESO devices 100a-b shown from a top-down/plan view, which are respectively implemented using the design of MESO device 100 from FIG. 1. Moreover, MESO devices 100a-b are cascaded, such that the differential output voltage contacts 106a-b (+−Vₒᵤₜ) of MESO device 100a are coupled to the differential input voltage contacts 104a-b (+−Vᵢₙ) of MESO device 100b. In this manner, the output of MESO device 100a drives the input of MESO device 100b. In actual embodiments, any number of MESO logic devices may be cascaded using any desired arrangement. For example, the input voltage contacts of each MESO device may be coupled to the output voltage contacts of one or more MESO devices, and vice versa.

FIG. 4 illustrates a flowchart 400 for forming integrated circuitry with MESO devices in accordance with certain embodiments. It will be appreciated in light of the present disclosure that the illustrated process flow is only one example methodology for arriving at the example MESO devices shown and described throughout this disclosure (e.g., MESO device 100, cascaded MESO logic 300). The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The illustrated process flow may be used to form one or more IC dies (e.g., semiconductor devices) that respectively include MESO devices with an interconnect (e.g., for signaling and power delivery). In some embodiments, the MESO devices and interconnect may collectively implement logic circuitry in the respective IC dies.

The flowchart begins at block 402 by receiving a substrate. In some embodiments, the substrate may be a DSO substrate, or a silicon substrate with a templating layer. Moreover, the substrate may be a wafer-level or panel-level substrate for wafer or panel process flows.

The flowchart then proceeds to block 404 to form a layer of MESO devices over the substrate. In some embodiments, the layer of MESO devices may be formed using the process flow of FIGS. 2A-D. For example, a stack of layers may be formed over the substrate (e.g., as shown in FIG. 2A), including a conductive contact layer for one of the differential voltage inputs (e.g., −V_{IN}), a magnetoelectric (ME) layer, a first ferromagnetic (FM) layer, an FM insulator layer, a second FM layer, an antiferromagnetic layer, a spin-orbit coupling (SOC) layer, and a spin-current absorbing layer. Some of the layers are then etched to form the requisite patterns for the MESO devices (e.g., as shown in FIGS. 2B-C). Finally, the remaining conductive contacts are formed for the respective MESO devices, including electrical contacts for the other differential voltage input (e.g., +V_{IN}), the different voltage outputs (e.g., +−V_{OUT}), power supply (e.g., I_{SUPPLY}), and ground (e.g., GND) (e.g., as shown in FIG. 2D).

The flowchart then proceeds to block 406 to form an interconnect for the MESO devices. For example, the interconnect may provide the requisite connections to and from the input (e.g., +−V_{IN}), output (e.g., +−V_{OUT}), power supply (e.g., I_{SUPPLY}), and ground (e.g., GND) contacts on the respective MESO devices.

In some embodiments, metallization/interconnect patterning processes may be used to form traces and vias for the interconnect. For example, multiple conductive (e.g., metal) layers may be formed over the MESO device layer, along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure). Moreover, conductive traces may be patterned (e.g., etched) in the conductive layers, and vias may be formed between conductive layers (e.g., through the intervening dielectric layers) to electrically couple traces in different conductive layers. The conductive traces and vias patterned in and between the conductive layers may collectively form the interconnect for the MESO devices.

The flowchart then proceeds to block 408 to perform any remaining processing, such as inter-layer dielectric (ILD) filling, planarization, interconnect bump formation, backside processing (e.g., for backside power delivery), etc. In wafer or panel process flows, the completed wafer or panel may be diced to singulate the IC dies on the wafer or panel. The singulated IC dies may then be incorporated into an IC package, circuit board, electronic device or system (e.g., electronic device 800), etc.

The singulated IC dies may include a variety of components and circuitry, including, without limitation, processing circuitry, communication circuitry, memory circuitry, and/or storage circuitry. In some embodiments, for example, the IC die(s) may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples.

At this point, the flowchart may be complete. In some embodiments, however, the flowchart may restart and/or certain blocks may be repeated. For example, in some embodiments, the flowchart may restart at block 402 to continue forming integrated circuitry with MESO devices with the same or similar design.

### Example Integrated Circuit Embodiments

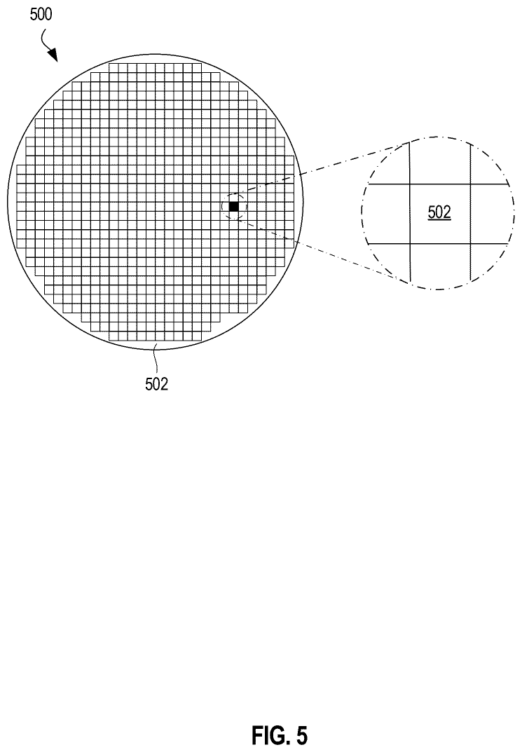

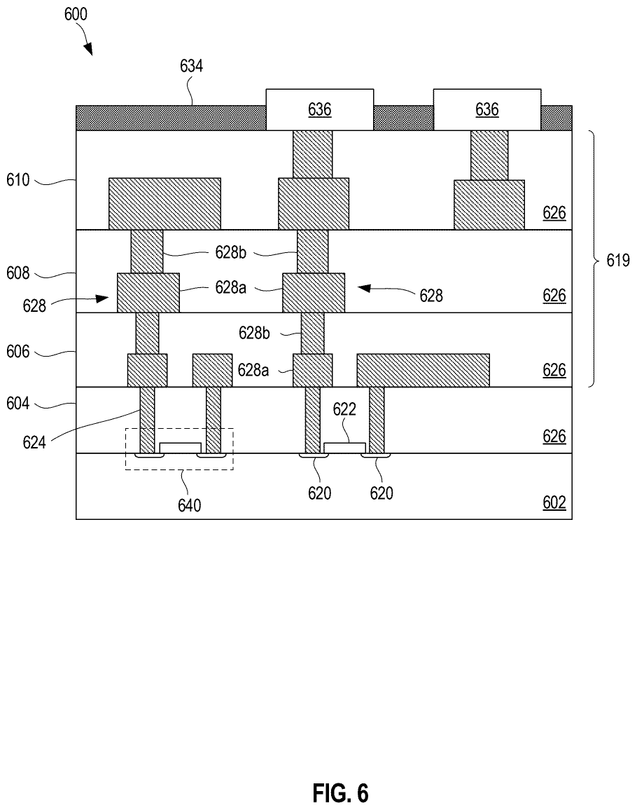

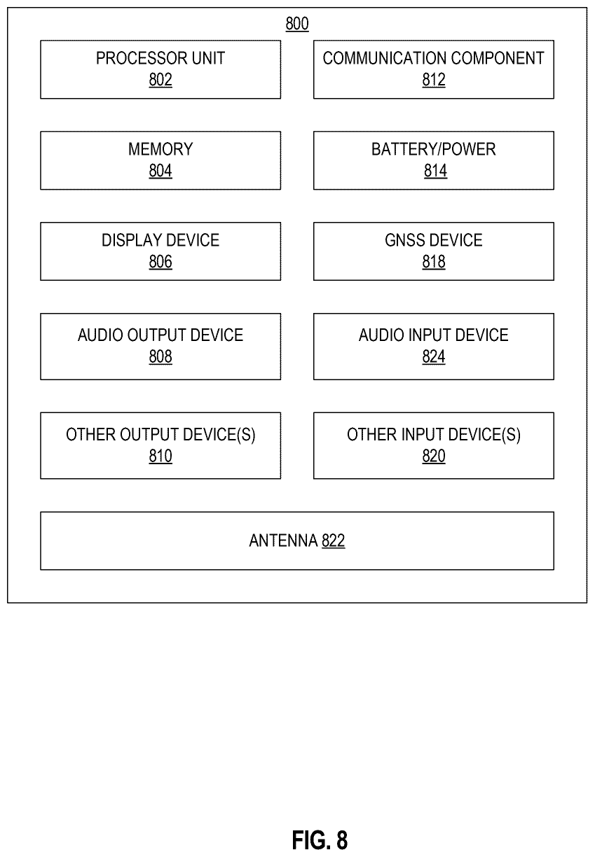

FIG. 5 is a top view of a wafer 500 and dies 502 that may be included in, or may include, any of the embodiments disclosed herein. In some embodiments, for example, the dies 502 may include one or more MESO devices (e.g., MESO device 100). The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may be any of the dies disclosed herein. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies are attached to a wafer 500 that include others of the dies, and the wafer 500 is subsequently singulated.

FIG. 6 is a cross-sectional side view of an integrated circuit device 600 that may be included in any of the embodiments disclosed herein (e.g., in any of the dies). One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components. The conductive contacts 636 may serve as any of the conductive contacts described throughout this disclosure.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636. These additional conductive contacts may serve as any of the conductive contacts described throughout this disclosure.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. These additional conductive contacts may serve as any of the conductive contacts described throughout this disclosure. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

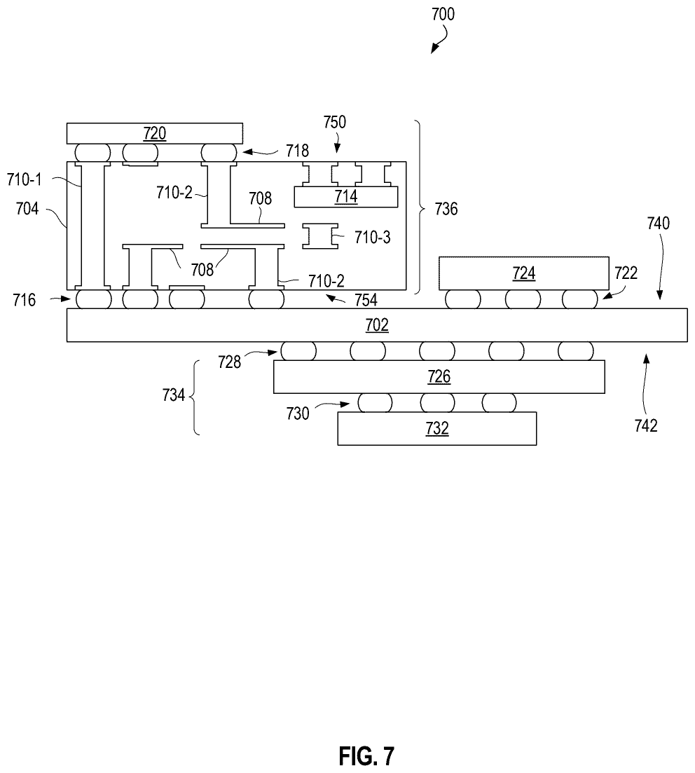

FIG. 7 is a cross-sectional side view of an integrated circuit device assembly 700 that may include any of the embodiments disclosed herein. In some embodiments, for example, the embedded devices 714 and/or IC components 720, 724, 726, 732 of the integrated circuit device assembly 700 may include one or more MESO devices (e.g., MESO device 100). In some embodiments, the integrated circuit device assembly 700 may be a microelectronic assembly. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742. Any of the integrated circuit components discussed below with reference to the integrated circuit device assembly 700 may take the form of any suitable ones of the embodiments of the microelectronic assemblies disclosed herein.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpackaged integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, the electrical device 800 and/or its respective components (e.g., communication components 812, processor units 802, memory 804) may include one or more MESO devices (e.g., MESO device 100), integrated circuit device assemblies 700, integrated circuit components 720, integrated circuit devices 600, or integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include other output device(s) 810 (or corresponding interface circuitry, as discussed above). Examples of the other output device(s) 810 may include an audio codec, a video codec, a printer, a wired or wireless transmitter for providing information to other devices, or an additional storage device.

The electrical device 800 may include other input device(s) 820 (or corresponding interface circuitry, as discussed above). Examples of the other input device(s) 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for case of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

The terms “substantially,” “close,” “approximately,” “near,” and “about” may refer to being within +/−10% of a target value unless otherwise specified.

Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In some embodiments, the phrase “A is located on B” or the phrase “A is adjacent to B” means that at least a part of A is in direct physical contact or indirect physical contact (having one or more other features between A and B) with at least a part of B. Moreover, the phrase “B is between A and C” means that at least part of B is in or along a space separating A and C and that the at least part of B is in direct or indirect physical contact with A and C.

The terms “coupled” and “connected” may refer to either a direct or indirect connection, such as a direct electrical, mechanical, or magnetic connection, or an indirect connection through one or more passive or active intermediary elements, components, or devices.

The phrases “in an embodiment,” “according to some embodiments,” “in accordance with embodiments,” “in embodiments,” and the like may each refer to one or more of the same or different embodiments.

The terms “comprises,” “comprising,” “includes,” “including,” “having” and the like specify the presence of the stated elements (e.g., features, components, materials, steps, operations) but do not preclude the presence or addition of one or more other elements.

The phrase “and/or” as used herein refers to and encompasses any and all possible combinations of one or more of the associated listed items.

The singular forms “a,” “an,” and “the” are intended to include the plural forms as well, unless the context clearly indicates otherwise. For example, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

For purposes of some embodiments, the transistors in various circuits and logic blocks described herein may be metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BICMOS, CMOS, cFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.). Moreover, in some embodiments, spintronic logic devices (e.g., magnetoelectric spin-orbit (MESO) logic devices) may be used in addition to, or as an alternative to, MOS transistors.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

In the foregoing description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure.

It is to be appreciated that the layers and materials described above are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted above may be fabricated on underlying lower level back end of line (BEOL) interconnect layers.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combination thereof.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a first layer comprising a magnetoelectric material; one or more second layers over the first layer, wherein the one or more second layers comprise one or more ferromagnetic materials; a third layer over the one or more second layers, wherein the third layer comprises an antiferromagnetic material; and a fourth layer over the third layer, wherein the fourth layer comprises at least one of a metal, a topological insulator, or a two-dimensional (2D) semiconductor material.

Example 2 includes the semiconductor device of Example 1, wherein the antiferromagnetic material comprises: nickel and oxygen; or cobalt and oxygen.

Example 3 includes the semiconductor device of any of Examples 1-2, further comprising a fifth layer over the fourth layer, wherein the fifth layer comprises ruthenium.

Example 4 includes the semiconductor device of Example 3, further comprising: a first conductive contact coupled to the first layer; a second conductive contact coupled to the one or more second layers; a third conductive contact coupled to the fourth layer and the fifth layer; and a fourth conductive contact coupled to the fourth layer and the fifth layer.

Example 5 includes the semiconductor device of Example 4, further comprising: a fifth conductive contact coupled to the one or more second layers, wherein the fifth conductive contact is further coupled to a power supply; and a sixth conductive contact coupled to the fifth layer, wherein the sixth conductive contact is further coupled to ground.

Example 6 includes the semiconductor device of any of Examples 1-5, wherein the one or more second layers are a plurality of second layers, wherein the plurality of second layers include: a first ferromagnetic layer, wherein the first ferromagnetic layer comprises a ferromagnetic material; a second ferromagnetic layer, wherein the second ferromagnetic layer comprises a ferromagnetic material; and a dielectric layer between the first and second ferromagnetic layers.

Example 7 includes the semiconductor device of any of Examples 1-6, wherein the magnetoelectric material comprises: bismuth, iron, and oxygen; lanthanum, bismuth, iron, and oxygen; terbium, manganese, and oxygen; or lutetium, iron, and oxygen.

Example 8 includes the semiconductor device of any of Examples 1-7, wherein the fourth layer comprises: the metal, wherein the metal comprises platinum, tantalum, or tungsten; the topological insulator, wherein the topological insulator comprises: bismuth and selenium; or bismuth and antimony; or the 2D semiconductor material, wherein the 2D semiconductor material comprises a transition-metal dichalcogenide or graphene.

Example 9 includes the semiconductor device of any of Examples 1-8, further comprising a magnetoelectric spin-orbit (MESO) device, wherein the MESO device comprises the first layer, the one or more second layers, the third layer, and the fourth layer.

Example 10 includes an electronic device, comprising: a substrate; and one or more magnetoelectric spin-orbit (MESO) devices over the substrate, wherein individual MESO devices comprise: a magnetoelectric layer; one or more ferromagnetic layers over the magnetoelectric layer; an antiferromagnetic layer over the one or more ferromagnetic layers; and a spin-orbit coupling (SOC) layer over the antiferromagnetic layer.

Example 11 includes the electronic device of Example 10, wherein the antiferromagnetic layer comprises: nickel and oxygen; or cobalt and oxygen.

Example 12 includes the electronic device of any of Examples 10-11, further comprising a spin absorption layer over the SOC layer.

Example 13 includes the electronic device of Example 12, wherein the spin absorption layer comprises ruthenium.

Example 14 includes the electronic device of any of Examples 12-13, further comprising: a first electrode coupled to the magnetoelectric layer; a second electrode coupled to the one or more ferromagnetic layers; a third electrode coupled to the SOC layer; a fourth electrode coupled to the SOC layer; a fifth electrode coupled to the one or more ferromagnetic layers, wherein the fifth electrode is further coupled to a power supply; and a sixth electrode coupled to the spin absorption layer, wherein the sixth electrode is further coupled to ground.

Example 15 includes the electronic device of any of Examples 10-14, wherein the SOC layer comprises an SOC material, wherein the SOC material has high spin-orbit coupling.

Example 16 includes the electronic device of Example 15, wherein the SOC material comprises a metal, a topological insulator, or a two-dimensional semiconductor material.

Example 17 includes the electronic device of any of Examples 10-16, further comprising an integrated circuit, wherein the integrated circuit comprises processing circuitry, memory circuitry, storage circuitry, or communication circuitry, wherein one or more of the MESO devices are comprised in the processing circuitry, the memory circuitry, the storage circuitry, or the communication circuitry.

Example 18 includes a method, comprising: receiving a substrate; forming a first layer over the substrate, wherein the first layer comprises a magnetoelectric material; forming one or more second layers over the first layer, wherein the one or more second layers comprise one or more ferromagnetic materials; forming a third layer over the one or more second layers, wherein the third layer comprises an antiferromagnetic material; and forming a fourth layer over the third layer, wherein the fourth layer comprises at least one of a metal, a topological insulator, or a two-dimensional (2D) semiconductor material.

Example 19 includes the method of Example 18, wherein the antiferromagnetic material comprises: nickel and oxygen; or cobalt and oxygen.

Example 20 includes the method of any of Examples 18-19, further comprising forming a fifth layer over the fourth layer, wherein the fifth layer comprises ruthenium.

1. A semiconductor device, comprising:
a first layer comprising a magnetoelectric material;
one or more second layers over the first layer, wherein the one or more second layers comprise one or more ferromagnetic materials;
a third layer over the one or more second layers, wherein the third layer comprises an antiferromagnetic material; and
a fourth layer over the third layer, wherein the fourth layer comprises at least one of a metal, a topological insulator, or a two-dimensional (2D) semiconductor material.

2. The semiconductor device of claim 1, wherein the antiferromagnetic material comprises:
nickel and oxygen; or
cobalt and oxygen.

3. The semiconductor device of claim 1, further comprising a fifth layer over the fourth layer, wherein the fifth layer comprises ruthenium.

4. The semiconductor device of claim 3, further comprising:
a first conductive contact coupled to the first layer;
a second conductive contact coupled to the one or more second layers;
a third conductive contact coupled to the fourth layer and the fifth layer; and
a fourth conductive contact coupled to the fourth layer and the fifth layer.

5. The semiconductor device of claim 4, further comprising:
a fifth conductive contact coupled to the one or more second layers, wherein the fifth conductive contact is further coupled to a power supply; and
a sixth conductive contact coupled to the fifth layer, wherein the sixth conductive contact is further coupled to ground.

6. The semiconductor device of claim 1, wherein the one or more second layers are a plurality of second layers, wherein the plurality of second layers include:
a first ferromagnetic layer, wherein the first ferromagnetic layer comprises a ferromagnetic material;
a second ferromagnetic layer, wherein the second ferromagnetic layer comprises a ferromagnetic material; and
a dielectric layer between the first and second ferromagnetic layers.

7. The semiconductor device of claim 1, wherein the magnetoelectric material comprises:
bismuth, iron, and oxygen;
lanthanum, bismuth, iron, and oxygen;
terbium, manganese, and oxygen; or
lutetium, iron, and oxygen.

8. The semiconductor device of claim 1, wherein the fourth layer comprises:
the metal, wherein the metal comprises platinum, tantalum, or tungsten;
the topological insulator, wherein the topological insulator comprises:
bismuth and selenium; or
bismuth and antimony; or
the 2D semiconductor material, wherein the 2D semiconductor material comprises a transition-metal dichalcogenide or graphene.

9. The semiconductor device of claim 1, further comprising a magnetoelectric spin-orbit (MESO) device, wherein the MESO device comprises the first layer, the one or more second layers, the third layer, and the fourth layer.

10. An electronic device, comprising:
a substrate; and
one or more magnetoelectric spin-orbit (MESO) devices over the substrate, wherein individual MESO devices comprise:
a magnetoelectric layer;
one or more ferromagnetic layers over the magnetoelectric layer;
an antiferromagnetic layer over the one or more ferromagnetic layers; and
a spin-orbit coupling (SOC) layer over the antiferromagnetic layer.

11. The electronic device of claim 10, wherein the antiferromagnetic layer comprises:
nickel and oxygen; or
cobalt and oxygen.

12. The electronic device of claim 10, further comprising a spin absorption layer over the SOC layer.

13. The electronic device of claim 12, wherein the spin absorption layer comprises ruthenium.

14. The electronic device of claim 12, further comprising:
a first electrode coupled to the magnetoelectric layer;
a second electrode coupled to the one or more ferromagnetic layers;
a third electrode coupled to the SOC layer;
a fourth electrode coupled to the SOC layer;
a fifth electrode coupled to the one or more ferromagnetic layers, wherein the fifth electrode is further coupled to a power supply; and
a sixth electrode coupled to the spin absorption layer, wherein the sixth electrode is further coupled to ground.

15. The electronic device of claim 10, wherein the SOC layer comprises an SOC material, wherein the SOC material has high spin-orbit coupling.

16. The electronic device of claim 15, wherein the SOC material comprises a metal, a topological insulator, or a two-dimensional semiconductor material.

17. The electronic device of claim 10, further comprising an integrated circuit, wherein the integrated circuit comprises processing circuitry, memory circuitry, storage circuitry, or communication circuitry, wherein one or more of the MESO devices are comprised in the processing circuitry, the memory circuitry, the storage circuitry, or the communication circuitry.

18. A method, comprising:
receiving a substrate;
forming a first layer over the substrate, wherein the first layer comprises a magnetoelectric material;
forming one or more second layers over the first layer, wherein the one or more second layers comprise one or more ferromagnetic materials;
forming a third layer over the one or more second layers, wherein the third layer comprises an antiferromagnetic material; and
forming a fourth layer over the third layer, wherein the fourth layer comprises at least one of a metal, a topological insulator, or a two-dimensional (2D) semiconductor material.

19. The method of claim 18, wherein the antiferromagnetic material comprises:
nickel and oxygen; or
cobalt and oxygen.

20. The method of claim 18, further comprising forming a fifth layer over the fourth layer, wherein the fifth layer comprises ruthenium.
